(19) United States
(12) Patent Application Publication
(10) Pub. No.: US 2021/0100098 A1
(43) Pub. Date: Apr. 1, 2021

(54) Long Coil Vias Optimization

(71) Applicant: Integrated Device Technology, Inc., San Jose, CA (US)

(72) Inventor: Gentjan QAMA, Munchen (DE)

(21) Appl. No.: 16/584,437

(22) Filed: Sep. 26, 2019

(51) Int. Cl. H05K 1/11; H05K 1/16; G01D 5/20

(52) U.S. Cl. CPC H05K 1/116; H05K 1/165; H05K 2201/09227; H05K 2201/10151; G01D 5/204

(57) ABSTRACT

A position sensor is presented. Embodiments of a position sensor according to some embodiments includes a printed circuit board and one or more receive coils formed on the printed circuit board, each of the one or more receive coils including first traces formed on a top surface of the printed circuit board, second traces formed on a bottom surface of the printed circuit board, and vias formed through the printed circuit board to connect the first traces with the second traces, wherein a correction area is formed with the first traces or the second traces that correct signals from the one or more receive coils resulting from signals from a bad area formed by the vias. long position sensor is presented.

### TECHNICAL FIELD

Embodiments of the present invention are related to position sensors and, in particular, to optimization of vias in a long-coil position sensor.

### DISCUSSION OF RELATED ART

Position sensors are used in various settings for measuring the position of one component with respect to another. Inductive position sensors can be used in automotive, industrial and consumer applications for absolute rotary and linear motion sensing. In many inductive positioning sensing systems, a transmit coil is used to induce eddy currents in a metallic target that is sliding or rotating above a set of receiver coils. Receiver coils receive the magnetic field generated from eddy currents and the transmit coils and provide signals to a processor. The processor uses the signals from the receiver coils to determine the position of the metallic target above the set of coils. The processor, transmitter, and receiver coils may all be formed on a printed circuit board (PCB).

Long position sensors, which are typically position sensors that span 10 cms or more in length, have a lot of uses, especially in cars, tractors, trucks, and other such functions. A long position sensor can replace more expensive sensors that may require a relatively large number of individual switches. The long position sensor can be controlled by a single integrated circuit chip and therefore occupies a relatively smaller space than alternatives. However, long position sensors suffer from larger non-linearity problems, which are harder to overcome.

Therefore, there is a need to develop better, more accurate inductive position sensing technologies.

### SUMMARY

A position sensor is presented. Embodiments of a position sensor according to some embodiments includes a printed circuit board and one or more receive coils formed on the printed circuit board, each of the one or more receive coils including first traces formed on a top surface of the printed circuit board, second traces formed on a bottom surface of the printed circuit board, and vias formed through the printed circuit board to connect the first traces with the second traces, wherein a correction area is formed with the first traces or the second traces that correct signals from the one or more receive coils resulting from signals from a bad area formed by the vias. long position sensor is presented.

A method of forming a position sensor according to some embodiments includes determining first traces of one or more receive sensors to be formed on a top surface of a printed circuit board; determining second traces of the one or more receive sensors to be formed on a bottom surface of a printed circuit board; determining vias that connect the first traces with the second traces; determining a bad area formed by connecting the first traces with the bottom traces with the vias; and determining a correction area to be formed in one of the first traces or the second traces based on the bad area and a magnetic field generated by a transmit coil, the correction area adjusting for effects from the bad area.

These and other embodiments are discussed below with respect to the following figures.

### BRIEF DESCRIPTION OF THE FIGURES

FIG. 1A illustrates a long coil position sensor.

FIG. 1B points out vias in the long coil position sensor illustrated in FIG. 1A.

FIG. 1C shows a close-up planar view of one of the via arrangements in the long coil position sensor illustrated in FIG. 1A.

FIGS. 2A and 2B illustrate a “eye shape” illustrating individual vias and demonstrating a problematic via.

FIG. 3 illustrates a via arrangement with compensation for effects of the problematic via.

FIGS. 4A and 4B illustrate a view of the “eye shape” in the x-y plane before and after compensation.

FIGS. 5A and 5B illustrate the sine signal along with an ideal sine signal from a long coil position sensor with and without optimization.

FIGS. 6A and 6B illustrate the cosine signal along with an ideal cosine signal from a long coil position sensor with and without optimization.

FIGS. 7A and 7B illustrates the measurement error in a long coil position sensor with and without optimization.

These and other aspects of embodiments of the present invention are further discussed below.

### DETAILED DESCRIPTION

In the following description, specific details are set forth describing some embodiments of the present invention. It will be apparent, however, to one skilled in the art that some embodiments may be practiced without some or all of these specific details. The specific embodiments disclosed herein are meant to be illustrative but not limiting. One skilled in the art may realize other elements that, although not specifically described here, are within the scope and the spirit of this disclosure.

This description illustrates inventive aspects and embodiments should not be taken as limiting—the claims define the protected invention. Various changes may be made without departing from the spirit and scope of this description and the claims. In some instances, well-known structures and techniques have not been shown or described in detail in order not to obscure the invention.

Embodiments of the present provide optimization structures to correct for non-linearities in the via structures of a long position sensor. These optimization structures can take the form of additional an additional area on a bottom of the printed circuit board (PCB) that can compensate for the adverse effects of the distortion cause by the vertical vias.

With regard to this application, sensor structures are formed on a top and a bottom of a printed circuit board (PCB) and coupled by conductive traces in vias through the PCB. Sensors are formed relative to a plane of the PCB, which is referred to as the plane of the PCB or the horizontal plane. Vias are then formed vertically through the PCB. All directions are referenced to the plane of the PCB with regard to the terms horizontal, vertical, top, and bottom regardless of the orientation of the PCB with respect to any other reference system.

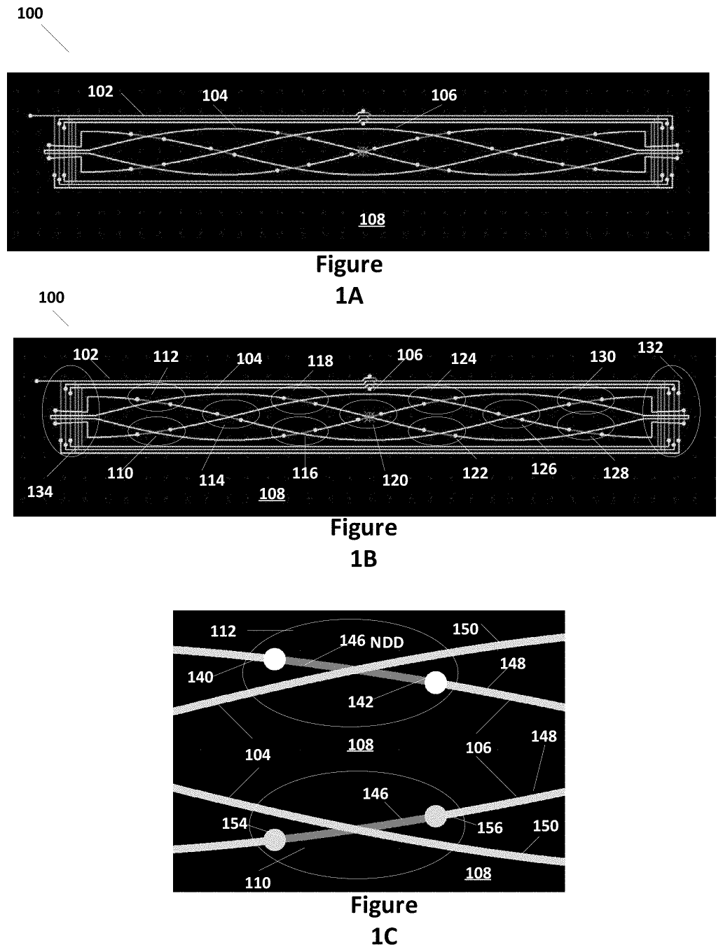

FIG. 1A illustrates a position sensor 100 formed on a circuit board (PCB) 108. FIG. 1A illustrates a view of the top surface of the PCB 108, although traces formed on the bottom surface of PCB 108 are also illustrated. As illustrated in FIG. 1A, position sensor 100 includes a transmitter coil 102, a sine coil 104, and a cosine coil 106. These coils are formed by traces on the top portion and bottom portion of PCB 108 and lie in the horizontal plane of circuit board 108. Position sensor 100 is coupled to a circuit (not shown) that drives transmitter coil 102 and receives signals from sine coil 104 and cosine coil 106. The circuit may calculate a position of a target over position sensor 100 from the signals received from sine coil 104 and the cosine coil 106.

During operation, transmitter coil 102 is driven to generate an electromagnetic field. Ideally in the absence of a conductive target (not shown), sine coil 104 and cosine coil 106 are formed with current loops where the induced magnetic field directly from transmitter coil 102 is canceled and results in no signal from sine coil 104 and cosine coil 106. In the presence of a target positioned over sine coil 104 and cosine coil 106, the electromagnetic field generated by transmitter coil 102 induces eddy currents in the target. The eddy currents in the target generate magnetic fields that in turn generate currents in sine coil 104 and cosine coil 106 that varies with the position of target over position sensor 100.

However, sine coil 104 and cosine coil 106 are not ideal. As shown in FIG. 1B, the traces that form sine coil 104 and cosine coil 106 are positioned both on the top and on the bottom of PCB 108 and connected with vias through PCB 108 in order that crossings of the traces can be performed. As illustrated in FIG. 1B, traces of sine coil 104 and cosine coil 106 cross each other in areas 110, 112, 116, 118, 122, 124, 128, and 130. Cosine coil crosses itself in area 114 and 126. Sine coil crosses itself in area 120. Traces on the top and bottom of PCB 108 are also illustrated as connected in areas 132 and 134, the ends of the receive oils 104 and 106.

As illustrated in FIG. 1C, which illustrates areas 110 and 112 as an example, traces 150 on the top of PCB 108 form sine coil 104. The traces of cosine coil 106 are formed with traces 148 on the top of PCB 108 and traces 146 formed on the bottom of PCB 108. FIG. 1C illustrates multiple areas where vias are used to connect traces traces 148 on the top of PCB 108 with traces 146 on the bottom of PCB 108 to completely form cosine coil 106. Areas 110 and 112 illustrate where traces 148 of cosine coil 106 are connected from the top of PCB 108 to traces 146 on the bottom of PCB 108 while trace 150 of sine coil 104 remain on the top of PCB 108.

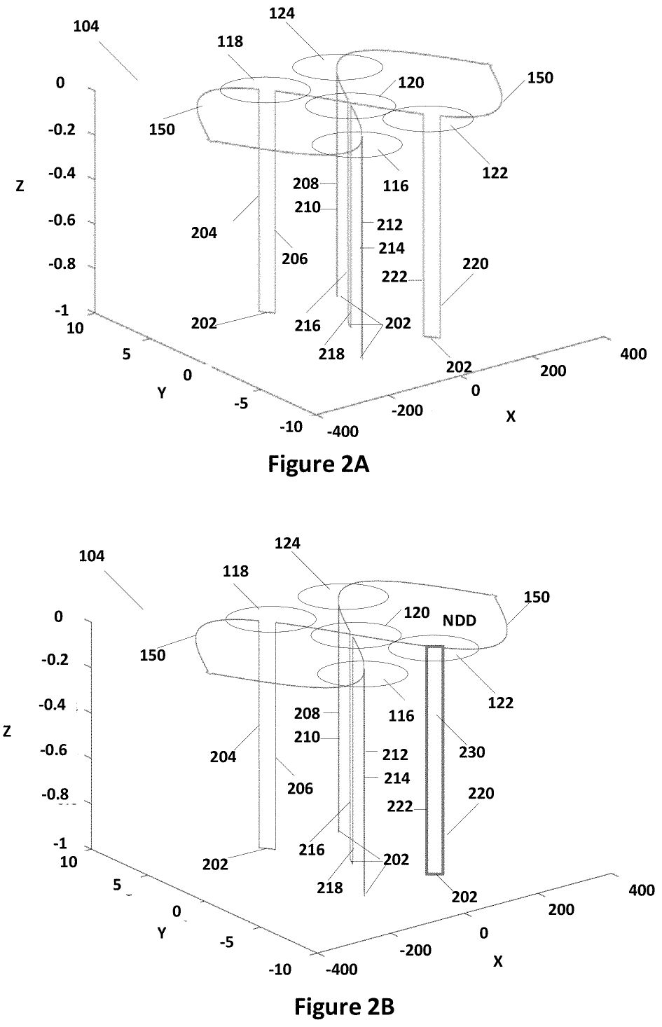

FIGS. 2A and 2B illustrate a three-dimensional graph of traces of sine coil 104. It should be understood that a three-dimensional graph of sine coil 104 is demonstrative of operation of both sine coil 104 and cosine coil 106. Three-dimensional graphs of cosine coil 106 may also be used to demonstrate the principles of the present invention and the choice of demonstrating sine coil 104 instead is arbitrary.

As illustrated in FIG. 2A, areas 116, 118, 120, 122, and 124 are illustrates. As discussed above, areas 116, 118, 122 and 124 illustrate areas where cosine coil 106 crosses sine coil 104 and area 120 is where sine coil 104 crosses itself Areas 110, 112, 128, and 130 are not illustrated because, in those crossings, trace 150 of sine coil 104 remains on the top of PCB 108. The graph illustrates the layout of traces 150 on the top of PCB 108 and traces 202 on the bottom of PCB 108 as a function of the coordinates X, Y, and Z. On the Z axis, “0” represents to the top of PCB 108 while “-1” represents the bottom of PCB 108. The Y axis is ranged from “10” to “−10” while the X axis is ranged from “−400” to “400”. The units of these measurements is arbitrary and represent the thickness, width, and extent of the coil. The units may be different in the three axis X, Y, and Z.

As illustrated in FIG. 2A illustrates the layout of trace 150 of sine coil 104, which is on the top of PCB 108 (not shown in FIG. 2A) and trace 202 of sine coil 104, which is on the bottom of PCB 108. As illustrated in FIG. 2A, in area 118, trace 150 is coupled with trace 202 with vias 204 and 206. In area 124, trace 150 is coupled with trace 202 with vias 208 and 210. In area 120 trace 150 is coupled to trace 202 with vias 216 and 218. In area 116, trace 150 is coupled to trace 202 with vias 212 and 214. In area 122, trace 150 is coupled with trace 202 with vias 220 and 222.

These vias, combined with any non-uniformity in the magnetic fields generated in transmit coil 102, can result in nonlinearities, sometime large nonlinearities, in the operation of position sensor 100. When a position sensor is relatively long (bigger than 20 or /30 cm) there is a huge non-linearity in the position sensor due to the vias. This nonlinearity coming from the layout of receiver coils 104 and 106, such as that illustrated in FIGS. 2A and. FIG. 2B illustrates a loop 230 in area 122 formed by vias 220 and 222 with trace 202 where receive coil 104 switches from the top trace 150 of sine coil 104 to the bottom trace 202 of sine coil 104. IN this consideration, the distance between two vias such as vias 222 and 220 (NDD) is important. The distance NDD (None Desired Distance) can be defined as the distance between two vias such as vias 220 and 222 in an area.

Ideally, the magnetic field at receive coils 104 and 106 is perpendicular to the plane of receive coils 104 and 106, which is the same as the plane of the top and bottom surfaces of PCB 108 on which traces forming receive coils 104 and 106 are formed. The physical phenomenal addressed by embodiments of the present invention result in non-linearity that is present because the electromagnetic field (EMF) generated by transmit coils 102 is not perfectly perpendicular to the plane of sine coil 104 and cosine coil 106. Consequently, there exists a component of the magnetic field that is parallel with the plane receive coils 104 and 106 (as defined by the top and bottom surfaces of PCB 108), and therefore is detected by loops formed by the vias in connection with traces 150 and 202, as is shown by loop 230 illustrated in FIG. 2B. Loop 230 is formed by vias 220, 222 in connection with trace 202 and trace 150.

The area of loop 230, referred to herein as the “bad area”, is given by A=t*NDD. As discussed above, NDD is defined by the distance between vias while t is the thickness of PCB 108. In some common cases, PCB has a thickness t of 1mm, which is a typical value, and the area of loop 230 is given by A=NDD mm². This area captures components of the magnetic field that are horizontal relative to the plane of receive coils 104 and 106 and with an X-Y component perpendicular to the area of loop 230. Consequently, from the Faraday-Neumann law an additional voltage will be generated in this area of the coils. In the example illustrated in FIGS. 2A and 2B, an additional voltage is generated by loop 230 that is proportional to the area and to the component of EMF parallel to the plane of receive coils 104 and 106. This effect is apparent in all of the Via areas and may be larger when the via area is closer to the transmitter coil.

Consequently, loops formed by vias in each of areas 116, 118, 120, 122, and 124 can contribute to the voltage measured in receive coil 104. This additionally generated voltage is interpreted by a circuit coupled to receive voltage from receive coils 104 and 106 as a deformation of the “good signal”.

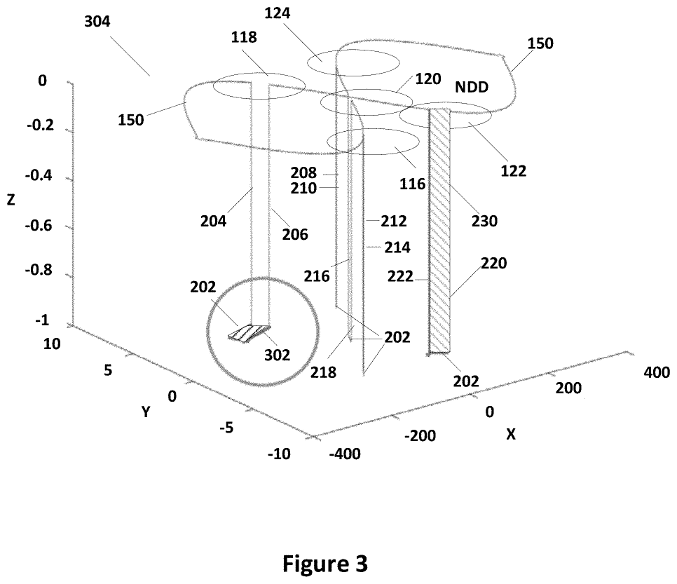

FIG. 3 illustrates a sine coil 304 according an embodiment of the present invention. As illustrated in FIG. 3, trace 202 is modified to include a compensation area 302. Compensation area 302 is sensitive to the normal component of the magnetic field and can be used to compensate for the effects of the vias and the vertical areas formed by the vias, which are sensitive to horizontal components of the magnetic field. In particular, area 302 can be arranged to substantially cancel the effects of the horizontally oriented magnetic fields captured by area 230. In particular the area of area 302 and the orientation of area 302 can be arranged to counteract the effects of area 230 on the signal from sine coil 304.

As discussed above, the “bad” vias effects in a receive coil such as coil 304 can be compensated by additional area 302 arranged in the same plane where receives coils including sine coil 304 are formed. The compensation area 302 can, for example, be created on the bottom of the PCB 108, in which case it is oriented perpendicular with the direction of the main magnetic field from transmitter coil 102. The compensation area 302 can compensate the effects of the vertical “bad area”, area 230 as illustrated in FIG. 3.

Compensation area 230, which as shown in FIG. 3 is on the XY plane at Z=−1, is capturing the main EMF component generated by transmitter coil 102, which has magnetic fields oriented in the vertical, or Z, direction. The compensation area 302 is capturing the vertical component of the magnetic field. It can be assumed that the magnetic fields generated by transmit coil 102, both the vertical and horizontal components, are uniform. In that case, B_{N} can be defined as the horizontal component of the magnetic field that is normal to the area 230. B_{Z} can be defined as main component of the magnetic field in the Z direction.

The additional area of compensation area 302 can be designated as Comp_area. The bad area resulting from the vias, area 230, can be designated Bad_area and is equal to t*NDD, where t is the thickness of PCB 108. With the assumption that the fields are uniform, then the following relationship holds:

B_{Z}*Comp_area=B_{N}*Bad_area

The value of Comp_area can then be given by

Comp_area=(B_{N}*Bad_area)/B_{Z}=(B_{N}/B_{Z})*Bad_area

The ratio (B_{N}/B_{Z}) can be estimated from a simulation tool given the layout of the transmission coils.

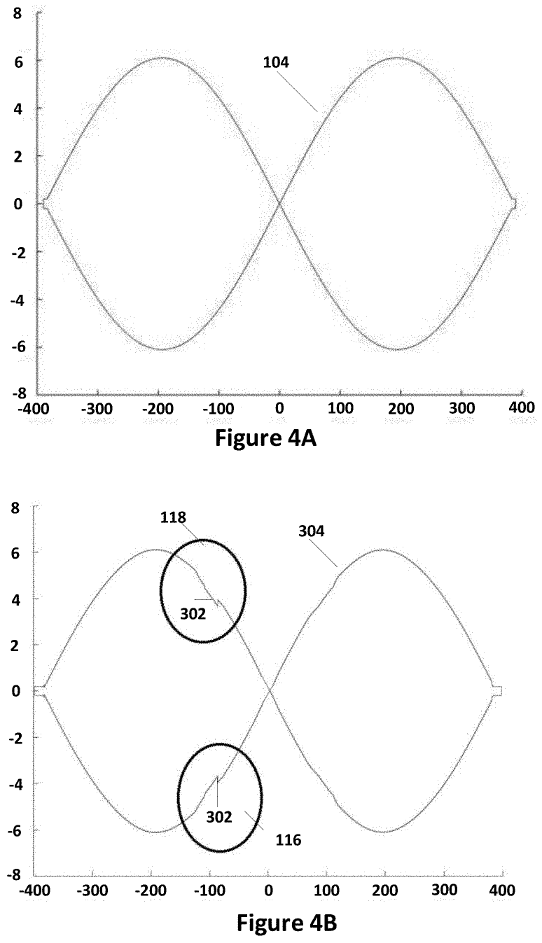

FIGS. 4A and 4B illustrate planar views of sine coil 104 and sine coil 304, respectively. FIG. 4B illustrates sine coil 304 according to some embodiments with correction areas 302 illustrated in areas 116 and 118. As illustrated, the correction areas 302 appear as a “jog” in the planar view of sine coil 304.

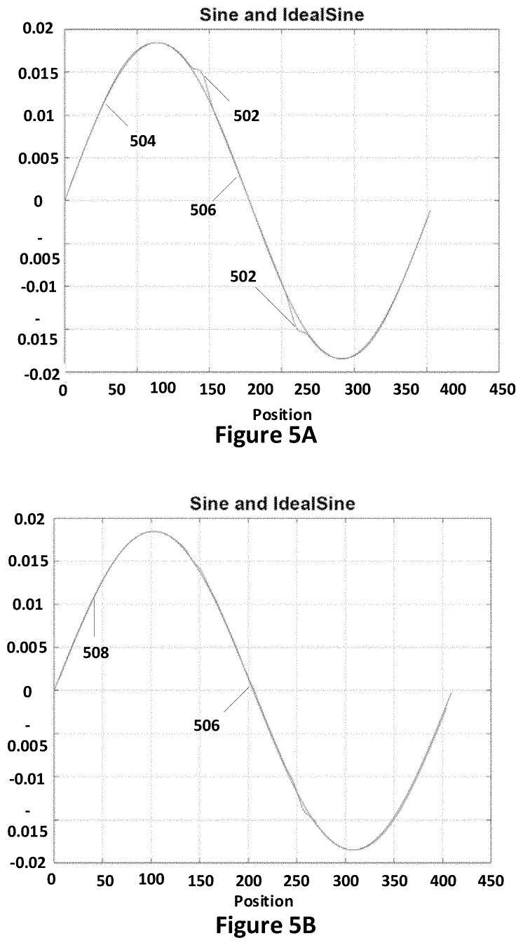

FIG. 5A illustrates the sine wave output 504 from the sine coil 104 overlaid with an ideal sine wave 506. As is illustrated in FIG. 5A, glitches 502 that show discrepancies between the actual output 504 and the ideal sine wave signal 506. FIG. 5B illustrates a measured output signal 508 from a sine coil 304 according to some embodiments compared with the ideal sine wave signal 506. As is illustrated in FIG. 5B, the glitches 502 have been substantially eliminated.

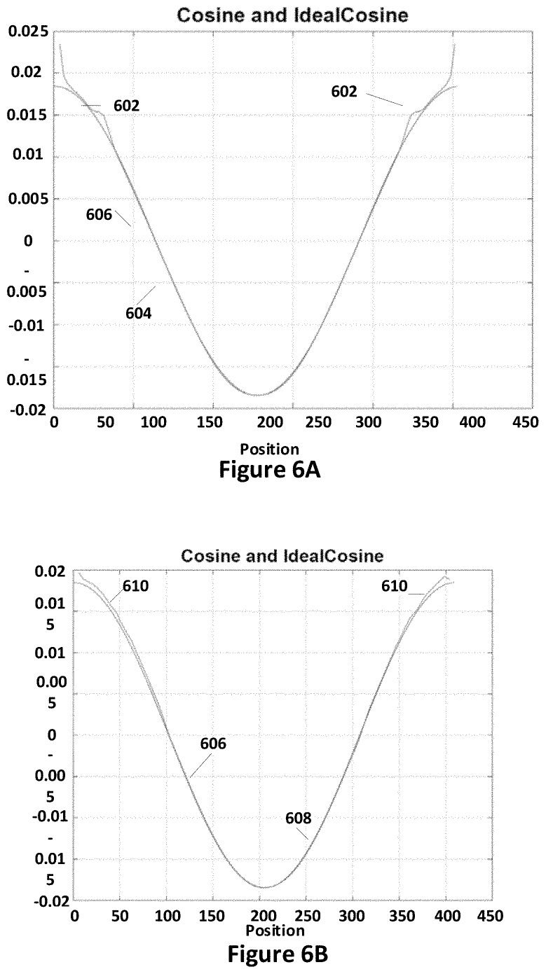

FIGS. 6A and 6B illustrate discrepancies between cosine coil outputs and ideal cosine signals. As illustrated in FIG. 6A, discrepancies 602 between the output signal 604 of cosine coil 106. FIG. 6B illustrates discrepancies 610 between cosine coil output 608 of a cosine coil according to embodiments of the present invention and the ideal cosine signal 606. As is illustrated, discrepancies 610 shown in FIG. 6B are much smaller than discrepancies 602 illustrated in FIG. 6A.

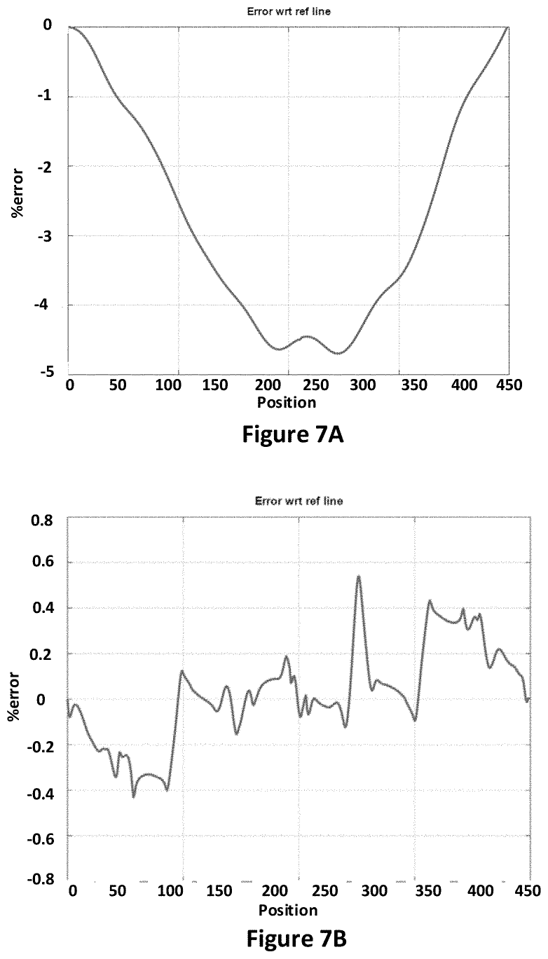

FIG. 7A illustrates the error, in percentage of Full Scale value, for the position as measured with sensor coils 104 and 106. FIG. 7B illustrates the percentage error using sensor coils according to embodiments of the present invention, sensor coil 304 and the corresponding cosine coil. As illustrated in FIG. 7A, the error is about 4.7% FS. After optimization as described herein, the error is reduced to about 0.5%. Sensor coils according to embodiments of the present invention, therefore, result in a improvement of a factor of about 9.

The above detailed description is provided to illustrate specific embodiments of the present invention and is not intended to be limiting. Numerous variations and modifications within the scope of the present invention are possible. The present invention is set forth in the following claims.

What is claimed is:

1. A position sensor, comprising:
a printed circuit board; and
one or more receive coils formed on the printed circuit board, each of the one or more receive coils including
first traces formed on a top surface of the printed circuit board;
second traces formed on a bottom surface of the printed circuit board; and
vias formed through the printed circuit board to connect the first traces with the second traces;
wherein a correction area is formed with the first traces or the second traces that correct signals from the one or more receive coils resulting from signals from a bad area formed by the vias.

2. The position sensor of claim 1, wherein the one or more receive coils includes a sine coil and a cosine coil.

3. The position sensor of claim 1, further including a transmit coil formed on the printed circuit board that generates a magnetic field B_{Z} that is normal to the top surface and the bottom surface of the printed circuit board.

4. The position sensor of claim 3, wherein the correction area is determined by calculating (B_{Z}/B_{N})*(bad area), where B_{N} is a magnetic field in the plane of the top surface and the bottom surface of the printed circuit board.

5. The position sensor of claim 4, wherein the bad area is given by the distance between adjoining vias times the thickness of the printed circuit board.

6. The position sensor of claim 5, wherein the magnetic fields B_{Z} and B_{N} can be determined by a simulation based on a construction of the transmitter coil and the one or more receive coils.

7. A method of forming a position sensor, comprising:
determining first traces of one or more receive sensors to be formed on a top surface of a printed circuit board;
determining second traces of the one or more receive sensors to be formed on a bottom surface of a printed circuit board;
determining vias that connect the first traces with the second traces;
determining a bad area formed by connecting the first traces with the bottom traces with the vias; and
determining a correction area to be formed in one of the first traces or the second traces based on the bad area and a magnetic field generated by a transmit coil, the correction area adjusting for effects from the bad area.

8. The method of claim 7, further including forming the first traces, the second traces, and the vias on the printed circuit board to form the position sensor.

9. The method of claim 7, wherein the one or more receive sensors includes a sine coil and a cosine coil.

10. The method of claim 7, wherein the bad area is given by a distance between adjacent vias time a thickness of the printed circuit board.

11. The method of claim 10, wherein the correction area is given by (B_{Z}/B_{N})*(the bad area), where B_{Z} is the component of the magnetic field generated by the transmit coil in the direction normal to the top surface and the bottom surface of the printed circuit board and B_{N} is the component of the magnetic field in the plane of the top surface and the bottom surface and normal to the bad area.
